(19) United States
(12) Patent Application Publication
(10) Pub. No.: US 2011/0133267 A1
(43) Pub. Date: Jun. 9, 2011

(54) METHOD OF FABRICATING SEMICONDUCTOR DEVICE AND THE SEMICONDUCTOR DEVICE

(75) Inventors: Kazuhiro Matsuo, Yokkaichi (JP); Masayuki Tanaka, Yokohama (JP); Hirofumi Iikawa, Yokkaichi (JP)

(73) Assignee: Kabushiki Kaisha Toshiba, Tokyo (JP)

(21) Appl. No.: 12/873,857

(22) Filed: Sep. 1, 2010

(30) Foreign Application Priority Data
Dec. 9, 2009 (JP) 2009-279382

(51) Int. Cl. H01L 29/788; H01L 21/28

(52) U.S. Cl. 257/316; 438/593; 257/E29.3; 257/E21.209

(57) ABSTRACT

A method of fabricating a semiconductor device includes forming a gate insulating film on a semiconductor substrate, forming a charge accumulation layer, an intermediate insulating film and a conductive layer sequentially on the gate insulating film, forming an electrode isolating trench in the conductive layer, the intermediate insulating film and the charge accumulation layer, forming a nitride film on upper and side surfaces of the conductive layer, side surfaces of the intermediate insulating film, side surfaces of the charge accumulation layer and an upper surface of the gate insulating film, removing the nitride film formed on the upper surface of the gate insulating film, and filling the electrode isolating trench with an insulating film.

### CROSS-REFERENCE TO RELATED APPLICATIONS

This application is based on and claims the benefit of priority from the prior Japanese Patent Application No. 2009-279382, filed on Dec. 9, 2009, the entire contents of which are incorporated herein by reference.

### FIELD

Embodiments described herein relate to a method of fabricating a semiconductor device provided with a plurality of memory cells comprising floating gate electrodes, control gate electrodes and interelectrode insulating films provided between the floating and control gate electrodes.

### BACKGROUND ART

A nonvolatile semiconductor device comprises a plurality of memory cells configured by floating gate electrodes, control gate electrodes and interelectrode insulating films provided between the floating and control gate electrodes. The memory cells are arranged in a direction of word lines and in a direction of bit lines. The control gate electrodes are continuous in the direction of word lines but separated in the direction of bit lines by insulating films. The memory cells are separated from each other by element isolation trenches continuous in the direction of the bit lines.

A distance between adjacent memory cells has been reduced and widths of a gate electrode and of a floating gate electrode have been scaled down with progress in device density. A distance between control gate electrodes is reduced with reduction in a distance between adjacent memory cells. In this configuration, when a large voltage is applied to a control gate electrode in order that a sufficient write threshold may be obtained, an electrical field between control and floating gate electrodes adjacent to each other is increased. This results in possible occurrence of write error onto the adjacent memory cells or of short circuit between adjacent control gate electrodes. Furthermore, since reduction in the distance between adjacent memory cells increases an interference effect between the adjacent memory cells, there is also a possibility of malfunction of elements. Still furthermore, reduction in the widths of floating and control gate electrodes sometimes increases variations in the width of the gate electrode when the width of gate electrode is reduced by post-oxidation. The width of gate electrode greatly affects a write characteristic. Accordingly, when variations in the widths of gate electrodes are increased by the post-oxidation, there is a possibility that variations in data write may be increased.

U.S. Pat. No. 7,078,813 discloses a nonvolatile semiconductor memory device having a structure that a silicon nitride film is formed as a barrier film on inner side surfaces of trenches separating gate electrodes in the direction of bit line, namely, on side surfaces of control gate electrodes, side surfaces of interelectrode insulating films and side surfaces of floating gate electrodes. In the disclosed device, however, the silicon nitride films remain on the bottoms of the trenches (that is, gate insulating films). Accordingly, even when the device density progresses, it is difficult to overcome the above-described write error, short circuit, malfunction or the like thereby to achieve sufficient reliability.

### BRIEF DESCRIPTION OF THE DRAWINGS

FIG. 1 is a schematic plan view of the structure in a non-volatile semiconductor device according to one embodiment;

FIG. 2 is a schematic sectional view taken along line 2-2 in FIG. 1;

FIG. 3 is a schematic sectional view taken along line 3-3 in FIG. 1;

FIG. 4 is a schematic sectional view taken along line 2-2 in FIG. 1, showing a first stage of fabrication process;

FIG. 5 is a schematic sectional view taken along line 2-2 in FIG. 1, showing a second stage of fabrication process;

FIG. 6 is a schematic sectional view taken along line 2-2 in FIG. 1, showing a third stage of fabrication process;

FIG. 7 is a schematic sectional view taken along line 2-2 in FIG. 1, showing a fourth stage of fabrication process;

FIG. 8 is a schematic sectional view taken along line 2-2 in FIG. 1, showing a fifth stage of fabrication process;

FIG. 9 is a schematic sectional view taken along line 2-2 in FIG. 1, showing a sixth stage of fabrication process;

FIG. 10 is a schematic sectional view taken along line 3-3 in FIG. 1, showing the first stage of fabrication process;

FIG. 11 is a schematic sectional view taken along line 3-3 in FIG. 1, showing the second stage of fabrication process;

FIG. 12 is a schematic sectional view taken along line 3-3 in FIG. 1, showing the third stage of fabrication process;

FIG. 13 is a schematic sectional view taken along line 3-3 in FIG. 1, showing the fourth stage of fabrication process;

FIG. 14 is a schematic sectional view taken along line 3-3 in FIG. 1, showing the fifth stage of fabrication process;

FIG. 15 is a schematic sectional view taken along line 3-3 in FIG. 1, showing the sixth stage of fabrication process;

FIG. 16 is a characteristic graph showing the relationship between leak current and impressed electric field;

FIG. 17 is a characteristic graph showing the relationship between the bases and doze amounts of nitrogen after radical nitridation process and after radical oxidation process; and

FIG. 18 is a view similar to FIG. 3, showing a second embodiment.

### DETAILED DESCRIPTION

In general, according to one embodiment, a method of fabricating a semiconductor device is disclosed. The method includes forming a gate insulating film on a semiconductor substrate, forming a charge accumulation layer, an intermediate insulating film and a conductive layer sequentially on the gate insulating film, forming an electrode isolating trench in the conductive layer, the intermediate insulating film and the charge accumulation layer, forming a nitride film on side surfaces of the conductive layer, side surfaces of the intermediate insulating film, side surfaces of the charge accumulation layer and an upper surface of the gate insulating film, removing the nitride film formed on the upper surface of the gate insulating film, and filling the electrode isolating trench with an insulating film.

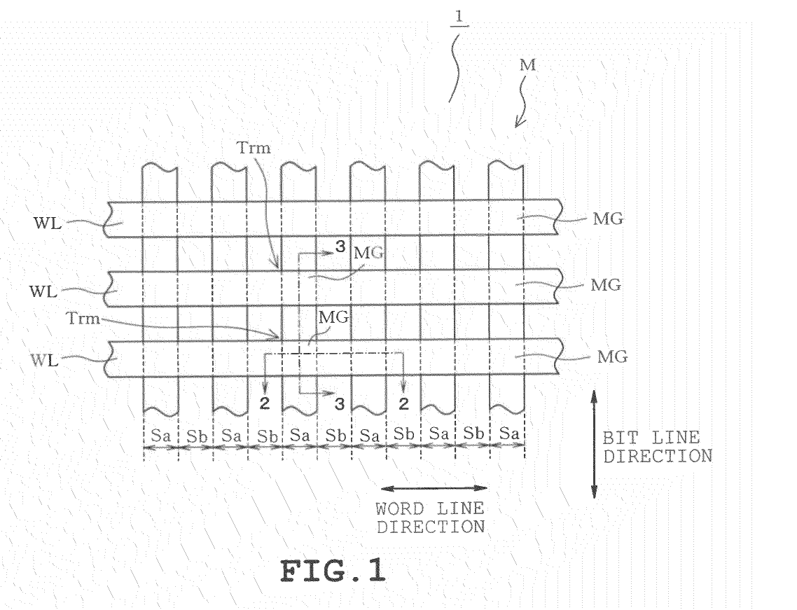

A first embodiment will be described with reference to FIGS. 1 to 17. The embodiment is applied to a nonvolatile semiconductor memory device. Identical or similar parts are labeled by the same reference symbols throughout the description. The drawings are schematic and differ from an actual product in the relationship between the thickness and planar dimensions, ratios of thicknesses of respective layers and the like.

Referring to FIG. 1, a number of memory cell transistors Trm are arranged in a matrix shape in directions of word lines and bit lines in a memory cell region M. Peripheral circuits (not shown) are configured to read, write and erase data stored on each memory cell transistor Trm. A NAND flash memory is exemplified as the nonvolatile semiconductor memory device having the above-described memory cell structure. The NAND flash memory is provided with a cell unit structure in which a plurality of memory cell transistors are series connected between two selective gate transistors.

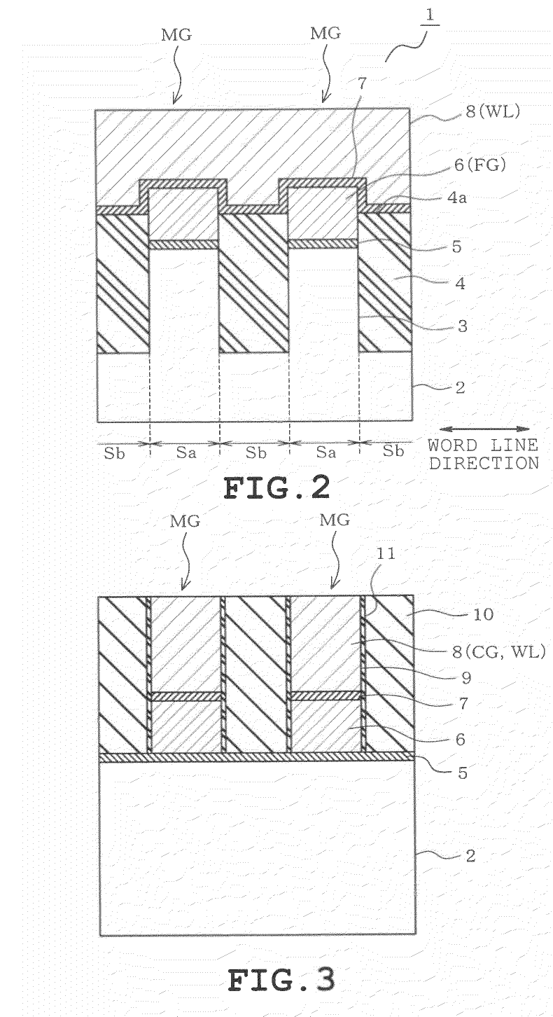

A silicon substrate 2 (semiconductor substrate) has a surface layer in which a plurality of element isolation trenches 3 are formed. The element isolation trenches 3 isolate the surface layer of the silicon substrate 2 into a plurality of active areas Sa extending in the direction of word lines in FIG. 2. The element isolation trenches 3 are filled with element isolation insulating films 4 respectively, so that element isolation regions Sb are configured. Each element isolation insulating film 4 includes a lower portion buried in the element isolation trench 3 and an upper portion protruding upward from the surface of the silicon substrate 2 (the active region Sa thereof). Each element isolation insulating film 4 is made of a silicon oxide film, for example.

Gate insulating films 5 (tunnel insulating films) are formed on the active regions Sa of the silicon substrate 2 divided by the element isolation regions Sb respectively. Each gate insulating film 5 is made of a silicon oxide film, for example. Floating gate electrodes FG are formed as charge accumulation layers on the gate insulating films 5 respectively. Each floating gate electrode FG is made of a polycrystalline silicon layer 6 (conductive layer) doped with impurities such as phosphor (P), for example. Each polycrystalline silicon layer 6 has a lower side surface serving as a contact surface which contacts an upper side surface of the element isolation insulating film 4 and an upper side surface protruding above the upper surface 4a of the element isolation insulating film 4.

An interelectrode insulating film 7 (an intermediate insulating film, an interpoly insulating film and an inter-conductive-layer insulating film) is formed on the upper surface 4a of the element isolation insulating film 4 and upper side surfaces and an upper surface of each floating gate electrode FG. The interelectrode insulating film 7 comprises an insulating film consisting of a high-dielectric-constant insulating film. Alternatively, the interelectrode insulating film 7 may comprise an insulating film made by stacking a silicon oxide film, a high-dielectric-constant insulating film and a silicon oxide film, or by stacking a silicon oxide film, a silicon nitride film and a silicon oxide film, or by stacking a silicon nitride film, a silicon oxide film, a silicon nitride film, a silicon oxide film and a silicon nitride film. Furthermore, a metal oxide film such as an aluminum oxide (Al₂O₃) may be desired as the high-dielectric-constant insulating film.

A conductive layer 8 is formed on the interelectrode insulating film 7 so as to extend in the direction of word lines. The conductive layer 8 functions as word lines WL which connect control gate electrodes CG of the respective memory cell transistors Trm. The conductive layer 8 comprises a polycrystalline silicon layer and a silicide layer made by siliciding any one of metals of tungsten, cobalt, nickel and the like and formed directly on the polycrystalline silicon layer. Each memory cell transistor Trm has a gate electrode MG comprising a stacked gate structure of the floating gate electrode FG, the interelectrode insulating film 7 and the control gate electrode CG.

The gate electrodes MG of the memory cell transistors Trm are juxtaposed in the direction of bit lines and are each isolated from the adjacent ones by the trenches 9 as shown in FIG. 3. The trenches 9 are filled with interlayer insulating films 10 respectively. Silicon nitride films 11 serving as insulating films which insulate the electrodes from each other are formed on inner side surfaces of each trench, that is, side surfaces of the gate electrode MG of the memory cell transistor Trm (side surfaces of the floating gate electrode FG, the interelectrode insulating film 7 and the control gate electrode CG). No silicon nitride film 11 is formed on the bottom of each trench 9 (an upper surface of each gate insulating film 5).

Diffusion layers (source/drain regions) which are not shown are formed at lower opposite sides of each gate electrode MG of the memory cell transistor Trm so as be located in the surface layer of the silicon substrate 2. Each memory cell transistor Trm includes the gate insulating film 5, the gate electrode MG and the source/drain regions.

In the nonvolatile semiconductor memory device 1 configured above, high electrical field from a peripheral circuit (not shown) is impressed between the word line WL and the silicon substrate 2, and a predetermined voltage is applied to each electric element (source/drain) so that data of the memory cell is erasable/rewritable.

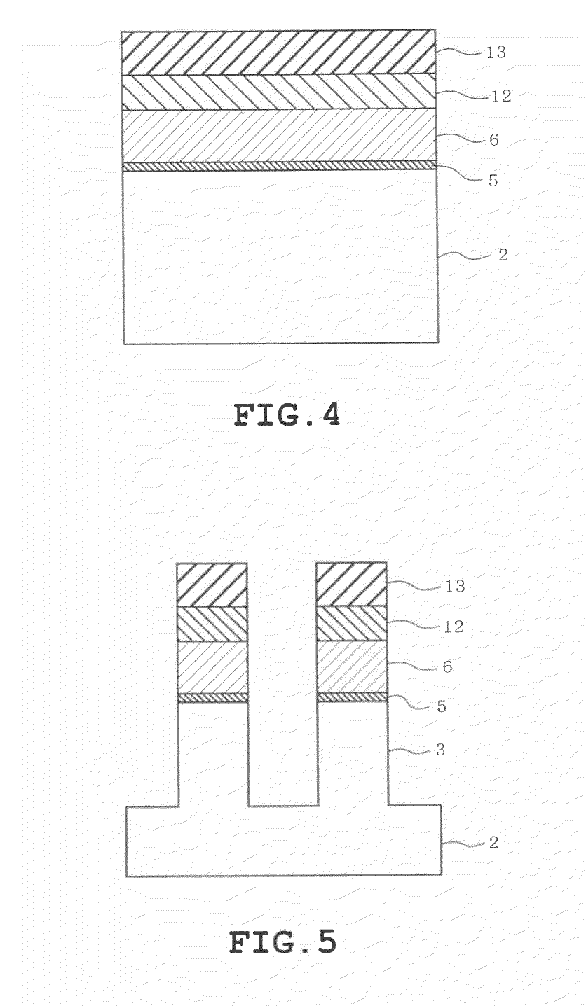

A method of fabricating the nonvolatile memory device configured above will now be described with reference to FIGS. 4 to 15. Firstly, the gate insulating film 5 (silicon oxide film) serving as a first insulating film is formed on a p-type silicon substrate (a silicon substrate having a p-type well in a surface layer) so as to have a film thickness ranging from 1 nm to 15 nm (see FIG. 4). A polycrystalline silicon layer 6 (the floating gate electrode FG) serving as a charge accumulation layer is formed on the gate insulating film 5 by a chemical vapor deposition (CVD) process so as to have a film thickness ranging from 10 nm to 200 nm. A silicon nitride film 12 is then formed on the polycrystalline silicon layer 6 by the CVD process so as to have a film thickness ranging from 50 nm to 200 nm. A silicon oxide film 13 is formed on the silicon nitride film 12 by the CVD process so as to have a film thickness ranging from 50 nm to 400 nm.

Subsequently, a photoresist (not shown) is applied to the surface of the silicon oxide film 13 and patterned by exposure and development. Next, the silicon oxide film 13 is etched with the photoresist serving as an etching mask with high etching resistance. The photoresist is removed after the etching, and the silicon nitride film 12 is etched with the silicon oxide film 13 serving as a mask. The polycrystalline silicon layer 6 (floating gate electrode FG), the gate insulating film 5 and the silicon substrate 2 are then etched so that the trenches 3 for element isolation are formed (see FIG. 5).

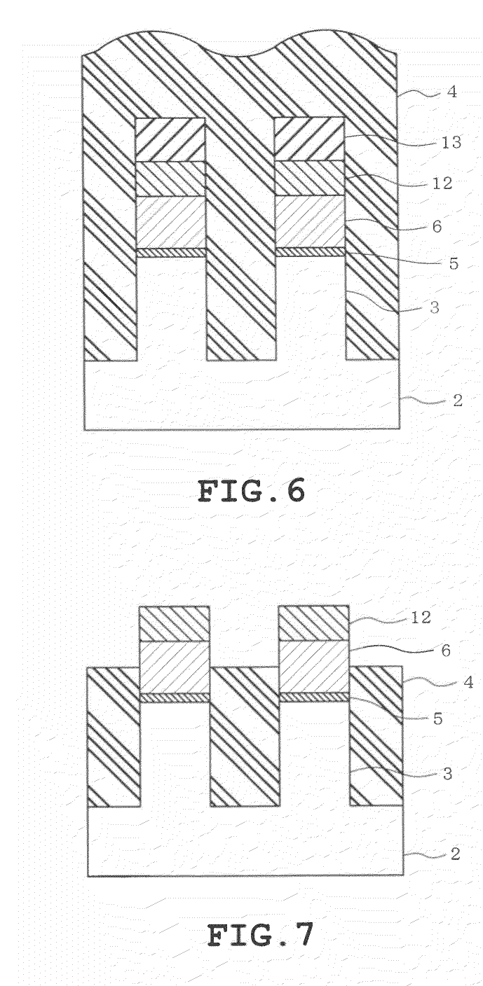

Subsequently, the element isolation insulating film (silicon oxide film) 4 is formed by a low-pressure chemical vapor deposition (LPCVD) or a coating technique so as to have a film thickness ranging from 200 nm to 1500 nm, whereby the trenches 3 are filled with the element isolation insulating film 4 (see FIG. 6). A heating treatment is applied to the element isolation insulating film 4 formed by the coating technique, in the presence of oxygen or moisture, so that high density growth is executed. Thereafter, the high-densified element isolation insulating film 4 is planarized by a chemical mechanical polishing (CMP) with the silicon nitride film 12 serving as a stopper. Subsequently, only the element isolation insulating film 4 is etched back with high etching selectivity to the silicon nitride film 12, whereupon the structure as shown in FIG. 7 is obtained. Thereafter, the silicon nitride film 12 serving as the mask is removed.

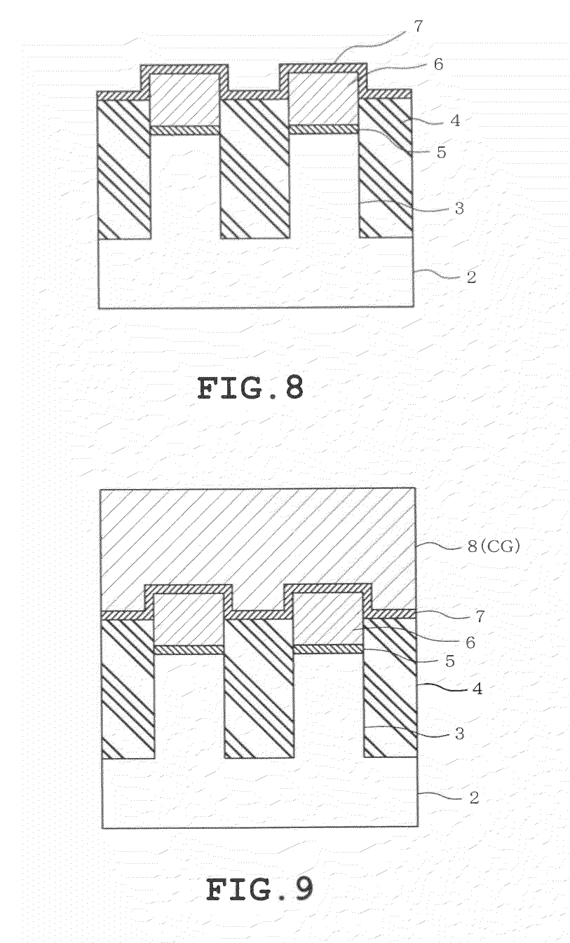

Subsequently, an interelectrode insulating film 7 serving as a second insulating film is formed on the surfaces of the exposed polycrystalline silicon layers 6 and the element isolation insulating films 4 as shown in FIG. 8. For example, a single high-dielectric insulating film is formed as the interelectrode insulating film by a known process. Alternatively, the aforesaid film with the stacked structure may be formed by a known process, instead of the single high-dielectric insulating film.

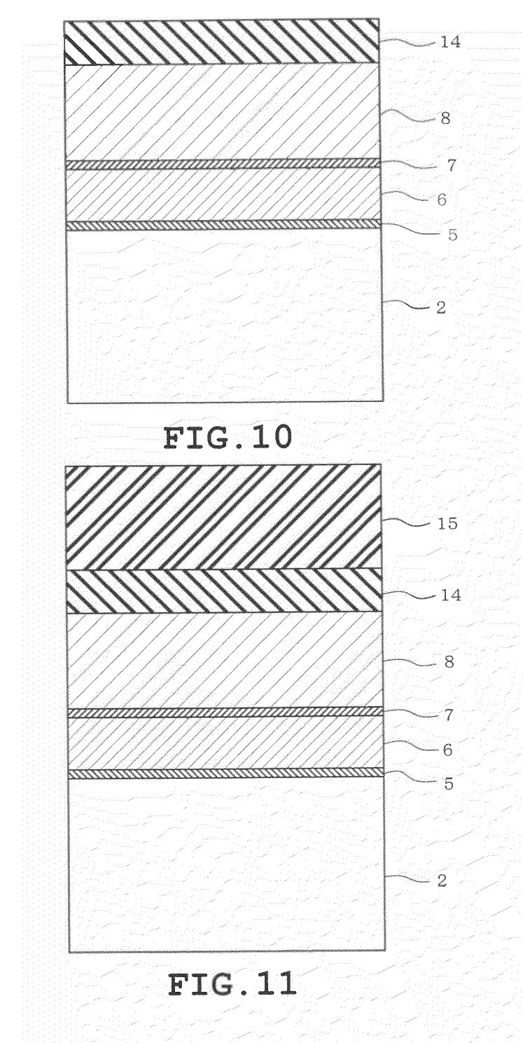

Subsequently, a conductive layer 8 (the control gate electrode CG) comprising a polycrystalline silicon layer is formed on the interelectrode insulating film 7 as shown in FIG. 9. A silicon nitride film 14 is then formed on the conductive layer 8 by the CVD process so as to have a film thickness ranging from 50 nm to 200 nm as shown in FIG. 10. Next, a silicon oxide film 15 is formed on the silicon nitride film 14 by the CVD process so as to have a film thickness ranging from 50 nm to 400 nm as shown in FIG. 11.

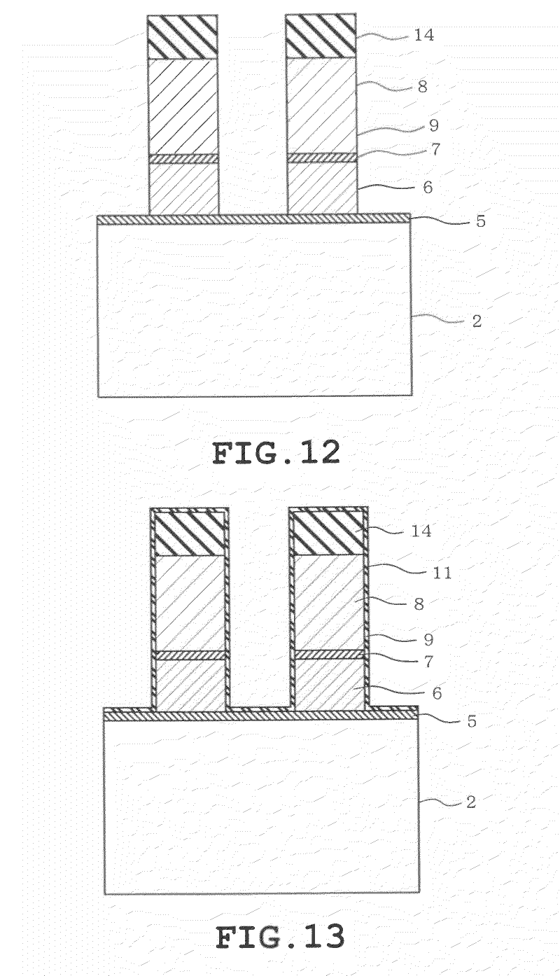

A photoresist (not shown) is thereafter applied to the silicon oxide film 15 and then patterned by exposure and development. Subsequently, the silicon oxide film 15 is etched using the photoresist which serves as a mask having a high resistance to etching. The photoresist is removed after the etching. The silicon nitride film 14 is then etched with the silicon oxide film 15 serving as a mask. The conductive layer 8, the interelectrode insulating film 7 and the polycrystalline silicon layer 6 are then etched so that the trenches 9 are formed which isolate the control gate electrode CG, the interelectrode insulating film 7 and the floating gate electrode FG in the direction of bit line. The silicon oxide film 15 is thereafter removed such that the structure as shown in FIG. 12 is obtained.

The silicon nitride film 11 is formed on the upper surface of the gate insulating film 5, the side surfaces of the polycrystalline silicon layers 6, the side surfaces of the interelectrode insulating films 7, the side surfaces of the conductive layers 8 and the side and upper surfaces of the silicon nitride films 14 as shown in FIG. 13. In this case, the silicon nitride film 11 is formed using a radical nitridation treatment in order to be rendered thin and controllable, as will be described in detail later.

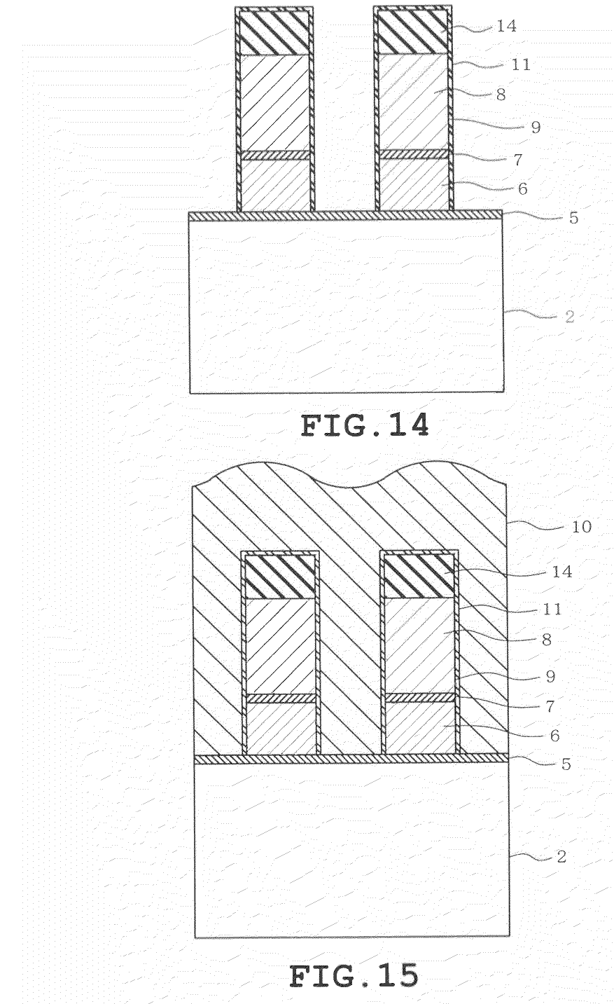

Subsequently, the silicon nitride film 11 on the gate insulating film 5 or the silicon oxide film is oxidized by a radical oxidation treatment so that the silicon nitride film 11 on the gate insulating film 5 (namely, on the bottom of the trench 9) is removed, whereby the structure as shown in FIG. 14 is obtained. This selective dissipation of the silicon nitride film 11 by the radical oxidation treatment will be described in detail later. Subsequently, an interlayer insulating film (a silicon oxide film) 10 is formed by the LPCVD process and the coating technique so as to have a film thickness ranging from 20 nm to 500 nm, whereby the trenches 9 for electrode isolation are filled with the interlayer insulating film 10. As a result, a configuration as shown in FIG. 15 is obtained.

The interlayer insulating film 10 is then etched back so that the silicon nitride film 11 is exposed. Silicide layers are formed on the upper surfaces of the conductive layers (polycrystalline silicon layers) 8 respectively after the silicon nitride films 11 and 14 of the exposed portion have been removed, whereby a structure as shown in FIG. 3 is obtained. Subsequently, processes of forming an interlayer insulating film, forming contacts, forming bit lines BL and an assembly and testing process and the like are executed, whereby the nonvolatile semiconductor memory device 1 is fabricated.

The following will describe treating manners of the radical nitridation treatment which is executed to form a silicon nitride film 11 as shown in FIG. 13 and a radical oxidation treatment which is executed subsequent to the radical nitridation treatment. Firstly, the radical nitridation treatment is characterized by the use of nitrogen physically excited by plasma or the like as nitriding species (nitrogen radical). In the radical nitridation treatment, an amount of nitridation depends upon treatment conditions and is arbitrarily adjustable. One of advantages of the radical nitridation treatment is that a silicon nitride film with high uniformity can be formed while a treatment temperature is maintained at a low level and a treatment time is reduced. In the embodiment, a microwave generating nitrogen radical ranges from 100 W to 3,000 W, a treatment pressure ranges from 5 to 30 Pa, and a substrate temperature ranges from a room temperature to 900° C. A silicon nitride film formed under the above-described conditions has a film thickness ranging from 0.3 nm to 5 nm, and a dose amount of nitrogen ranges from 1.0×10¹⁴ [atoms/cm²] to 1.0×10¹⁸ [atoms/cm²].

Next will be described a radical oxidation treatment which is executed after the forming of the silicon nitride film. In the radical oxidation treatment, oxidation is executed with an oxidizing agent produced by reaction of a hydrogen gas and an oxygen gas. Treatment conditions for radical oxidation treatment in the embodiment areas follows. A hydrogen gas ratio ranges from 0.5% to 10% of a flow rate of hydrogen-oxygen gas mixture. A treatment temperature ranges from 700° C. to 1,000° C. An amount of oxidation (thickness of oxide film) in the radical oxidation treatment is arbitrarily adjustable depending upon treatment conditions. The radical oxidation treatment is characterized in that a treatment time can be reduced and a long-distance transportation of oxidizing species in a silicon nitride film can be realized. The radical oxidation treatment can remove the silicon nitride film 11 above the gate insulating film 5, namely, on the bottom of the trench 9 as shown in FIG. 14.

There is a possibility of variations in thresholds with increase in fixed charge and/or increase in an interface state when the silicon nitride film 11 is directly formed on side surfaces of the floating gate electrode FG after the electrode isolating trenches 9 have been formed (see FIG. 12). When the variations in the thresholds with increase in the fixed charge and/or the increase in the interface state cannot be allowed in the device, a thin silicon oxide film with a thickness of about 1 nm to about 2 nm is sometimes formed on the floating gate electrode FG, namely, on the side surfaces of the polycrystalline silicon layer 6 by a chemical oxidation process in order that interface characteristics may be adjusted. Furthermore, a very thin native oxide is sometimes formed on the side surfaces of the floating gate FG, namely, on the polycrystalline silicon layer 6. Thus, when the thin silicon oxide film having a film thickness of about 2 nm or below is formed on the side surfaces of the polycrystalline silicon layer and the silicon nitride film 11 is subsequently formed on the thin silicon oxide film and the radical oxidation treatment is then executed, there can be a possibility that the silicon nitride film 11 on the side surfaces of the polycrystalline silicon layer 6 may oxidize thereby to be removed. The inventors have confirmed by experiments or the like that the silicon nitride film 11 cannot be removed from the side surfaces of the polycrystalline silicon layer 6.

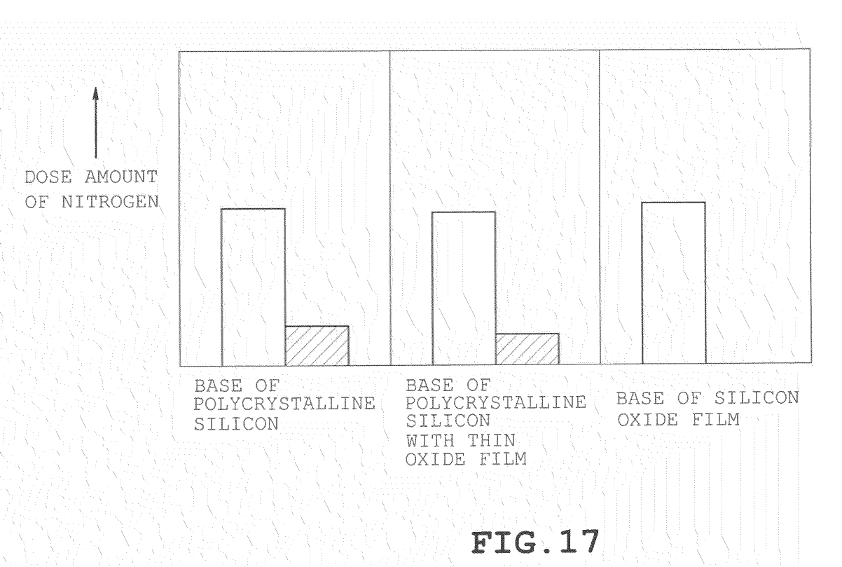

More specifically, three types of bases were prepared: a first base of polycrystalline silicon, a second base obtained by forming a thin silicon oxide film (having a film thickness of about 1 nm) on polycrystalline silicon and a third base of silicon oxide film having a film thickness of about 10 nm. A silicon nitride film was formed on each base by the above-described radical nitridation treatment, and thereafter, a radical oxidation treatment was executed. FIG. 17 shows the results of the experiment. As shown by blank bar graphs in FIG. 17, the silicon nitride films formed on the respective bases have substantially the same amount of nitridation (namely, dose amount of nitrogen). Furthermore, as shown by shaded bar graphs in FIG. 17, when the radical oxidation treatment is executed after the forming of the silicon nitride film, an amount of nitridation is reduced but a remaining amount of nitridation is sufficient in each of the case where the base of polycrystalline silicon was used and the case where the thin silicon oxide film was formed on the base of polycrystalline silicon. However, it can be understood that the nitride film on the base of silicon oxide film disappears. The aforementioned experimental result shows that execution of oxidation of the nitride film diffuses nitrogen outward.

Furthermore, the reason for dissipation of the silicon nitride film on the silicon oxide film by the radical oxidation treatment is that the base of silicon oxide film has a lower silicon density than the base of polycrystalline silicon and the base of polycrystalline silicon on which the thin silicon oxide film is formed and accordingly, a silicon nitride film formed in the radical nitridation is considered to become fragile. As a result, the silicon nitride film on the silicon oxide film can be dispersed by the radical oxidation treatment, and the nitride film can selectively be caused to remain on the polycrystalline silicon or the base obtained by forming the thin silicon oxide film on the polycrystalline silicon.

An amount of nitrogen and a film thickness thereof remaining on the polycrystalline silicon vary depending upon the amount of nitrogen and a film thickness of the silicon nitride film initially formed by the radical nitridation treatment and the conditions of oxidation treatment of the radical oxidation treatment. Accordingly, the conditions of the nitridation and oxidation treatments are controlled in the respective radical nitridation and oxidation treatments so that an amount of nitrogen and a film thickness of the silicon nitride film remaining on the polycrystalline silicon assume desired values respectively.

In the meanwhile, the method of removing the silicon nitride film on the bottom of each trench 9 includes one in which the silicon nitride film is formed by the LPCVD process and thereafter, an anisotropic etching may be executed to remove the silicon nitride film 11. In this method, however, it is difficult to form, on the side surfaces of the gate electrode, a silicon nitride film which is uniform and has a smaller number of trap sites. The reason for the difficulty will be described in the following.

The control gate electrodes CG, the interelectrode insulating film 7, the floating gate electrodes FG, and the element isolation insulating films 4 are processed in forming the electrode isolating trenches 9. Since the films have different etching rates in the processing, irregularities are formed on the inner side surfaces of each trench 9. An anisotropic etching is executed after uniform silicon nitride films have been formed on the irregular side surfaces of each trench 9. The silicon nitride film on the bottom of each trench 9 is scraped thereby to dissipate since an etching in the vertical direction relative to the silicon substrate progresses in the anisotropic etching. In this case, only the silicon nitride film on the upper surfaces of convex portions is etched on the inner side surfaces of each trench 9 to be thinned, and no silicon nitride film on upper surfaces of concave portions is etched. Furthermore, in many cases, fixed charge and/or trap sites are accordingly formed in the silicon nitride film formed by the LPCVD process due to damages caused by the subsequent anisotropic etching. For the foregoing reason, it is desirable that the radical nitridation treatment and the radical oxidation treatment each as described above in the foregoing embodiment be executed.

According to the foregoing embodiment as described above, the silicon nitride films 11 are formed on the side surfaces of the floating gate electrodes FG and the control gate electrodes CG. This can reduce leak current produced between the control gate electrodes CG or between the floating gate electrode FG and the control gate electrode CG adjacent to each other during data write. Consequently, data write error can be suppressed, and a nonvolatile semiconductor memory device which is excellent in transistor operation can be realized.

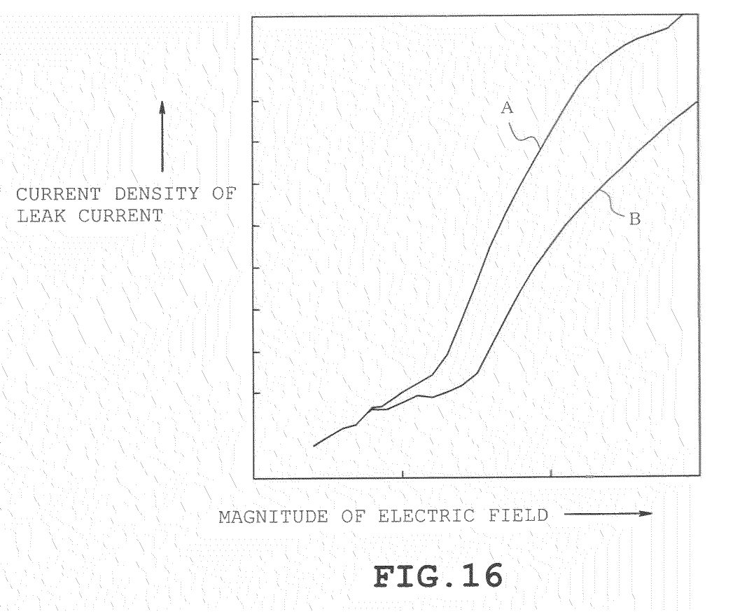

The inventors conducted an experiment to confirm that the leak current could be reduced by the forming of the silicon nitride film 11 as described above. More specifically, curve A in FIG. 16 shows the result of measurement of current density of leak current which flowed when only the silicon oxide film was provided and electric field was impressed on the silicon oxide film. An axis of abscissas denotes the magnitude of electric field, and an axis of ordinate in FIG. 16 denotes the magnitude of the current density of the leak current. Curve B in FIG. 16 denotes the result of measurement of the current density of the leak current flowing when the electric field was impressed on the configuration composed by inserting a silicon nitride film between electrodes in addition to a silicon oxide film.

According to FIG. 16, leak current can be reduced to a larger extent in the case where the silicon nitride film was inserted than in the case where no silicon nitride film was inserted. In this case, the film thickness of the insulating film where a conduction band crosses corresponds to an electron tunnel distance. The tunneling probability becomes smaller as the electron tunnel distance is long. Accordingly, when a silicon nitride film having a higher dielectric constant than a silicon oxide film is formed immediately proximal to electrons to be injected, it is considered that the tunnel distance of electrons is increased such that leak current is reduced.

The leak current produced by the electric field is also affected by a barrier height of the film through which the leak current passes. In particular, it is known that an effect of suppressing a leak current is obtained in a low electric field region in which the electron tunneling distance is increased and which has a higher barrier height. In order that this advantage may effectively be used, oxygen may be taken into the nitride film so that an oxynitride film is formed. On the other hand, when variations in working due to postoxidation which will be described later are taken into consideration, a nitride film containing no oxygen has a higher barrier performance against an oxidation agent than the aforementioned oxynitride film, thereby being more effective.

In the case where a distance between the control gate electrodes CG is reduced by variations in the fabrication of electrode isolating trenches 9 in the nonvolatile semiconductor memory device, the electric field impressed on the insulating film between the gate electrodes during data write becomes large, whereupon the leak current is increased. Adverse effects of the variations in the fabrication of the above-described trenches 9 are increased when increase in the leak current due to increase in the electric field is large. Accordingly, there is a possibility that the number of memory cells in which erroneous data writing occurs may be increased. On the other hand, the silicon nitride film 11 is formed on the side surfaces of the floating gate electrodes FG and control gate electrodes CG in the foregoing embodiment. As a result, the leak current between the floating and control gate electrodes FG and CG can be reduced as compared with the conventional configuration, whereupon sufficient margin is provided for the variation in the electric field. This can reduce erroneous data writing and increase a range of allowance for the variation in the working and reduce erroneous data writing in the whole wafer. In this case, since the effect of reduction in the leak current by the nitride film depends upon the film thickness thereof, it is desirable that the film thickness of the nitride film be uniform. On the contrary, since the silicon nitride film 11 is formed by the radical nitridation treatment in the foregoing embodiment, the silicon nitride film 11 with a uniform thickness can be formed.

Oxidation is sometimes carried out after the forming of the electrode isolating trenches 9 in order that damage to the oxide film during fabrication and/or deposited oxide film may be reformed. Furthermore, an oxidation agent sometimes oxidizes an electrode during the forming of the deposited oxide film (oxidation in the assembly and testing process). Variations in the width of the control gate electrode CG are increased by the variations in the fabrication of the electrode isolating trenches 9 and variations in an amount of oxidation in the assembly and testing process. Since a width of the gate electrode affects write characteristics to a large extent, the variations in the width of gate electrode due to the oxidation in the assembly and testing process increase variations in the write characteristics.

On the other hand, the silicon nitride film 11 formed on the side surfaces of the floating gate electrodes FG and the control gate electrodes CG has the effect of suppressing diffusion of the oxidizing agent. Accordingly, the reduction in the width of the gate electrode due to oxidation in the assembly and testing process can be suppressed, whereupon the variations in the writing of data can be suppressed. Furthermore, since the side surfaces of the interelectrode insulating film 7 are protected by the silicon nitride film 11, occurrence of bird beak due to oxidation during the assembly and testing process can be suppressed. In this case, in order that the floating gate and control electrodes FG and CG may be protected from the oxidizing agent, it is desirable that the silicon nitride film 11 formed on the side surfaces of these electrodes have a uniform film thickness. Since the silicon nitride film 11 is formed by the radical nitridation treatment in the embodiment, the film thickness of the silicon nitride film can be rendered uniform.

Furthermore, no silicon nitride film 11 is formed on the bottom of each electrode separating trench 9 in the foregoing embodiment as shown in FIG. 3. The reason for this is that there is a possibility of deterioration of device operation due to parasitic capacity when a film having a high dielectric constant such as a nitride film is formed on an insulating film located between electrodes. Additionally, an increase in interference between adjacent memory cells results in reduction in the writing speed or malfunction in write onto an adjacent memory cell. In the foregoing embodiment, however, an adverse effect of the nitride film can be reduced since no silicon nitride film 11 is formed on the bottom of each electrode isolating trench 9. Furthermore, when the film thickness of the silicon nitride film 11 remaining between the memory cells, an inter-cell interference effect varies the characteristics of the device. Accordingly, it is desirable that the film thickness of the silicon nitride film be uniform. In the foregoing embodiment, however, the silicon nitride film 11 having a uniform film thickness can be formed since the silicon nitride film 11 is formed by the radical nitridation treatment.

Furthermore, a silicon nitride film is formed with fixed charge in many cases. When formed on the substrate lateral to a tunnel insulating film (the bottom of the electrode isolating trench 9), the fixed charge causes threshold shift, which may result in failures of the device. The silicon nitride film forms a trap site which traps charge by hot electron injection or the like when high electric field is impressed on the device during writing. This sometimes results in failure in transistor characteristics such as threshold variation. Moreover, when the silicon nitride film has a poor film quality, the trapped charge is moved through a trap site by the electric field established by electron stored in the floating gate electrode FG. More specifically, the charge movement causes deterioration of the charge retention characteristic, which may deteriorate the reliability of the device. However, since no silicon nitride film is formed on the bottom of each electrode isolating trench 9 in the foregoing embodiment, leak current can be reduced between the electrodes while concern to the device failure is reduced. Furthermore, the gate electrodes can be protected from an oxidizing agent, whereupon the effective width of the electrode can be maintained.

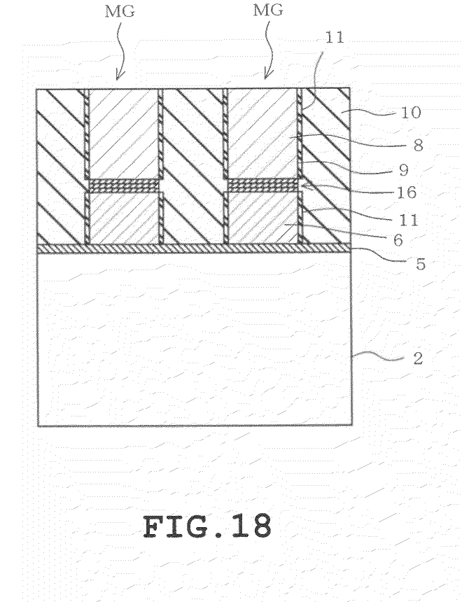

FIG. 18 illustrates a second embodiment. In the second embodiment, identical or similar parts are labeled by the same reference symbols as those in the first embodiment. An insulating film having a structure containing an oxide film is used as the interelectrode insulating film in the second embodiment. For example, the interelectrode insulating film is an oxide-nitride-oxide (ONO) film 16 comprising a silicon oxide film/silicon nitride film/silicon oxide film. A nitride film formed on the side surfaces of the ONO film 16 by the radical nitridation treatment is oxidized by the radical oxidation treatment thereby to dissipate. This results in a structure as shown in FIG. 18, in which structure the silicon nitride film 11 is discontinuous between the side surfaces of the floating gate electrode FG and the control gate electrode CG. The nonvolatile semiconductor memory device of the second embodiment has the same structure as of the first embodiment in the other respect than described above.

In the configuration of the second embodiment, when a trap site is formed in the silicon nitride film 11 formed on the side surfaces of the gate electrode MG, the charge is trapped into the silicon nitride film 11 during writing. However, the movement of the trapped charge by the charge established by the electron stored in the floating gate electrode FG can be suppressed, more specifically, the movement of charge through the trap in the silicon nitride film 11 can be suppressed. Accordingly, the concern regarding deterioration of charge retention characteristic can be wiped out such that a desired effect can be achieved. Furthermore, the effect of reforming the edge portion of the ONO film 16 can be achieved by the reach of the oxidation agent to the ONO film (interelectrode insulating film) 16. This can form the interelectrode insulating film having a good leak current characteristic. Furthermore, the silicon nitride film 11 formed on the silicon oxide film in the silicon oxide film exposed after electrode forming evaporates. As a result, the effect of reducing leak current between the electrodes can be achieved while the remaining silicon oxide film and/or deposited silicon oxide film in the electrode forming is annealed for reformation. Additionally, since the gate electrodes MG are protected from the oxidizing agent, the width of the gate electrode MG can be prevented from being reduced.

Furthermore, the ONO film 16 containing the silicon oxide film is used as the interelectrode insulating film and is interposed between the silicon nitride films 11 formed on the side surfaces of the floating and control gate electrodes FG and CG, whereby the ONO film 16 and the silicon nitride films 11 are configured into a stacked structure. Accordingly, there is no concern for deterioration of the charge retention characteristic, and the adverse effects of the bird beak can be reduced while the edges of the floating gate electrode FG and the control gate electrode CG are reformed by the post-oxidation with the result of improvement of the leak current characteristic. More specifically, since the bird beak is formed by the oxidizing agent reaching the side surfaces of the floating gate electrode and the oxidizing agent diffused in the silicon oxide film, oxidation progresses more as the oxidizing agent comes close to the side surfaces. On the other hand, in the second embodiment, the oxidizing agent diffused in the interlayer insulating film 10 is suppressed by the silicon nitride films 11 formed in the trenches 9 between the gate electrodes MG. Consequently, the edges of the floating gate electrode FG are just rounded at the most, whereupon occurrence of bird beak can be suppressed.

The foregoing embodiments should not be restrictive but can be modified or expanded as follows. Although the radical nitridation process is employed as the method of forming the silicon nitride film 11 (see FIG. 13) in the foregoing embodiments, the forming method should not be limited to the process. A plasma nitridation process or a usual thermal nitridation process by use of an electric furnace may be employed as the forming method, instead.

Furthermore, although the radical oxidation process is employed in the case where the silicon nitride film 11 on the bottom of the trench 9 is removed, the removing method should not be limited to the radical oxidation process. The silicon nitride film may be removed by a wet oxidation process, a dry oxidation process, an ozone oxidation process or the like, instead. This oxidation process may be divided into several parts when an amount of oxidation can be adjusted so that the silicon nitride film 11 does not disappear from the side surfaces of the floating gate electrodes FG and control gate electrodes CG. There is not a specific limit on the number of divided parts of the oxidation process.

Additionally, although applied to the nonvolatile semiconductor memory device having the floating gate electrodes, each embodiment may be applied to a semiconductor device having another gate electrode structure if the device has a stacked structure similar to that of the device in each embodiment. Of course, the same effect as in each foregoing embodiment can be achieved in this case. For example, the semiconductor device having another gate electrode structure may be a nonvolatile semiconductor memory device having a charge-trap type cell structure (referred to as “MONOS”) using a silicon nitride film as a charge trap layer (charge accumulation layer).

While certain embodiments have been described, these embodiments have been presented by way of example only, and are not intended to limit the scope of the invention. Indeed, the novel methods and systems described herein may be embodied in a variety of other forms; furthermore, various omissions, substitutions and changes in the form of the methods and systems described herein may be made without departing from the spirit of the invention. The accompanying claims and their equivalents are intended to cover such forms or modifications as would fall within the scope and spirit of the invention.

What is claimed is:

1. A method of fabricating a semiconductor device comprising:
forming a gate insulating film on a semiconductor substrate;
forming a charge accumulation layer, an intermediate insulating film and a conductive layer sequentially on the gate insulating film;
forming an electrode isolating trench in the conductive layer, the intermediate insulating film and the charge accumulation layer;
forming a nitride film on side surfaces of the conductive layer, side surfaces of the intermediate insulating film, side surfaces of the charge accumulation layer and an upper surface of the gate insulating film;
removing the nitride film formed on the upper surface of the gate insulating film; and
filling the electrode isolating trench with an insulating film.

2. The method according to claim 1, wherein in the forming of the nitride film, the nitride film is formed by physically excited nitrogen.

3. The method according to claim 1, wherein in the removing of the nitride film, the nitride film is removed by an oxidation treatment.

4. The method according to claim 3, wherein an oxidation agent produced by reaction between oxygen and hydrogen is used in the oxidation treatment.

5. The method according to claim 1, wherein in the forming of the nitride film, the nitride film is formed by a plasma nitridation process or a thermal nitridation process by use of an electric furnace.

6. The method according to claim 3, wherein in the oxidation treatment, wet oxidation, dry oxidation or ozone oxidation is used.

7. The method according to claim 1, wherein the nitride film is an oxynitride film.

8. The method according to claim 1, wherein before execution of the forming of the nitride film, an oxide film having a film thickness of 2 nm or below is formed on the side surfaces of the charge accumulation layer.

9. The method according to claim 8, wherein the oxide film formed on the side surfaces of the charge accumulation layer is formed by a chemical oxidation method.

10. The method according to claim 8, wherein the oxide film formed on the side surfaces of the charge accumulation layer is a native oxide film.

11. The method according to claim 1, wherein:
a silicon oxide film is formed as the gate insulating film;
a polycrystalline silicon layer is formed as the charge accumulation layer;
a high-dielectric-constant insulating film is formed as the intermediate insulating film;
a polycrystalline silicon layer is formed as the conductive layer; and
a silicon nitride film is formed as the nitride film.

12. The method according to claim 1, wherein:
a silicon oxide film is formed as the gate insulating film;
a polycrystalline silicon layer is formed as the charge accumulation layer;
an insulating film which is configured so as to include an oxide film is formed as the intermediate insulating film;
a polycrystalline silicon layer is formed as the conductive layer; and
a silicon nitride film is formed as the nitride film.

13. The method according to claim 12, wherein in execution of the removing of the nitride film, the nitride film formed on the side surfaces of the intermediate insulating film is also removed.

14. A semiconductor device comprising:
a semiconductor substrate;
a gate insulating film formed on the semiconductor substrate;
a plurality of gate electrodes which are formed on the gate insulating film and each of which has a stacked structure of a floating gate electrode, an interelectrode insulating film and a control gate electrode; and
an interlayer insulating film filling a trench defined between the gate electrodes,
wherein a nitride film is formed on inner side surfaces of the trench between the gate electrodes; and
no nitride film is formed on a bottom of the trench between the gate electrodes.

15. The device according to claim 14, wherein the nitride film on the inner side surfaces of the trench is formed by a radical nitridation treatment.

16. The device according to claim 14, wherein an oxide film having a film thickness of 2 nm or below is formed on side surfaces of the floating gate electrode of the inner side surfaces of the trench between the gate electrodes.

17. A semiconductor device comprising:
a semiconductor substrate;
a gate insulating film formed on the semiconductor substrate;
a plurality of gate electrodes which are formed on the gate insulating film and each of which has a stacked structure of a floating gate electrode, an interelectrode insulating film and a control gate electrode; and
an interlayer insulating film filling a trench defined between the gate electrodes,
wherein the trench has inner side surfaces, and a nitride film is formed on a first part of the inner side surfaces corresponding to the floating gate electrode and a second part of the inner side surfaces corresponding to the control gate electrode, the inner side surfaces including a third part corresponding to the interelectrode insulating film, the third part having no nitride film formed thereon, the trench having a bottom on which no nitride film is formed.

18. The device according to claim 17, wherein:
the semiconductor substrate comprises a silicon substrate;
the gate insulating film comprises a silicon oxide film;
the floating gate electrode comprises a polycrystalline silicon layer;
the interelectrode insulating film comprises an insulating film which is configured so as to include an oxide film; and
the control gate electrode comprises a polycrystalline silicon layer; and
the nitride film comprises a silicon nitride film.

19. The device according to claim 17, wherein the nitride film on the first and second parts of the inner side surfaces of the trench is formed by a radical nitridation treatment.

20. The device according to claim 17, wherein an oxide film having a film thickness of 2 nm or below is formed on side surfaces of the floating gate electrode of the inner side surfaces of the trench between the gate electrodes.
